(19) United States
(12) Patent Application Publication
(10) Pub. No.: US 2011/0186899 A1
(43) Pub. Date: Aug. 4, 2011

(54) SEMICONDUCTOR DEVICE WITH A VARIABLE INTEGRATED CIRCUIT CHIP BUMP PITCH

(75) Inventor: Petrus Johannes Gerardus van Lieshout, Eindhoven (NL)

(73) Assignee: Polymer Vision Limited, Eindhoven (NL)

(21) Appl. No.: 12/699,644

(22) Filed: Feb. 3, 2010

(51) Int. Cl. H01L 33/00; H01L 21/66

(52) U.S. Cl. 257/99; 438/17; 257/E21.529; 257/E33.066

(57) ABSTRACT

A semiconductor device is described that comprises an integrated circuit substrate comprising a plurality of bonding pads for enabling electrical connectivity to a chip circuit. The bonding pads are at least partially covered by a passivation layer having pre-manufactured holes. The device also includes a chip having a plurality of bumps atop the bonding pads, wherein areas of the bumps are larger than respective areas of cooperating holes in the passivation layer.

### FIELD OF THE INVENTION

The invention relates to a semiconductor device. In particular, the invention relates to a semiconductor device including a variable pitch of integrated circuit (IC) chip bumps on a substrate. The invention further relates to a method for manufacturing an integrated circuit.

### BACKGROUND OF THE INVENTION

Tolerances for bonding integrated circuit (IC) chips on substrates, for example on displays, have become increasingly important with the increase in number of components in electronic systems and the increase in the number of connections per IC. More particularly, IC bonding on flexible display substrates is challenging due to at least the following reasons. Uncertainties in dimensions between the IC chips and such substrates cause misalignment of connections and unintended open and shortened connections. Such uncertainties arise from changes in material dimensions and/or uncertainties in material dimensions.

One example of this problem is flip-chip bonding, also referred to as chip-on-glass bonding. Flip-chip bonding provides a convenient way to make a large number of electrical connections between a silicon IC chip and a large substrate, such as a display backplane. The pattern and spacing of the IC bumps on the IC chip is fixed at manufacture. The IC chip bumps and bonding pads on the substrate have, therefore, to be accurately matched to provide good electrical connections. The substrate, however, can change size due to manufacturing stresses causing distortion of a pattern of the bonding pads. Alignment errors may result when the pattern and/or spacing of the bonding pads, manufactured to match the pattern and spacing of the IC chip bumps, change due to, for example, shrinkage of the substrate.

### SUMMARY OF THE INVENTION

It is found that flexible substrates, for example, flexible displays, are dimensionally unstable, giving rise to a sizing mismatch, for example, during bonding of fine-pitch silicon IC chips onto such flexible substrates.

Embodiments of the invention provide a semiconductor device comprising an IC chip or a flip chip enabling mitigation of misalignment problems occurring due to changes of size of a substrate the IC chip is conceived to be electrically connected to. In particular, it is an object of the invention to provide a semiconductor device with bump pitch variation possibilities whereby misalignment problems between substrate's bonding pads and IC bumps are counteracted.

To this end according to an aspect of the invention the semiconductor device comprises an integrated circuit (IC) chip including a plurality of electrodes arranged in at least one row for enabling electrical connectivity to an IC chip circuit. The electrodes have centerlines in a direction transverse to a row direction. Moreover, a plurality of bumps arranged atop the electrodes form respective bump-electrode pairs. The bumps have centerlines in a direction transverse to the row direction, wherein positions of bump centerlines with respect to electrode centerlines for the bump-electrodes pairs are different for different locations on the IC chip.

This technical measure is based on the insight that different bump sizing may be provided by allowing a lateral shift between respective centerlines of the bumps and the centerlines of the electrodes thereby enabling manufacturing of differently sized bump sets using substantially the same chip architecture. This insight applies to an IC design when the electrodes are arranged either with or without a passivation layer. For the latter case, when a passivation layer at least partially covers the electrodes, the passivation layer may include pre-manufactured holes forming respective connectivity areas on the electrodes of the IC chip.

By way of a particular example, surface areas of bumps are larger than connectivity areas of the electrodes. In particular, a dimension of the bumps in a direction of a lateral shift with respect to the electrodes may be larger than a respective dimension of the connectivity areas of the electrodes. This has an effect that an extension of a bump outside the connectivity area of the electrode is possible without degrading electrical properties of the bump-electrode connection. Such extension enables manufacturing of differently pitched bumps which may preserve correct alignment between the bumps and the bonding pads of a suitable substrate even when an original pattern of the bonding pads is distorted, for example, due to substrate shrinkage. This is of particular advantage for flexible substrates, wherein size instability may be pronounced in both x- and y-directions. When an area of a bump is larger than the connectivity area of the electrode, increased shifts between the bumps and the electrodes are achievable. Such shifts relate, for example, to lateral shifts, i.e., shifts in direction of electrode rows.

It will be appreciated that the variable IC chip bump pitch may be achieved by applying different bump maskers. Alternatively, one may re-design the complete IC chip, for example, by allowing a pitch of the electrodes to vary. These embodiments are further discussed with reference to FIG. 3.

In the semiconductor device according to embodiments of the invention, respective placements of the bumps onto the cooperating connectivity area of the electrodes are different for different locations on the IC chip.

Because an area of a bump is larger than an area of a corresponding connectivity area of the electrode that the bump is deposited onto, the bump has a greater degree of freedom with respect to a lateral displacement, in comparison to a bump design known from the art. Therefore, when a substrate is to be connected to an IC chip, a correspondingly sized IC may be selected for bonding. Such IC chip may comprise a bump array centered with regard to a corresponding connectivity area of a chip's central electrode, while lateral bumps may demonstrate off-centered shift of the bump with regard to further chips' electrodes. By providing widened bumps with respect to the connectivity area of the electrodes such off-center alignment may still be sufficient for providing a reliable electrical contact between the bumps and the IC chip electrodes. This effect will be discussed in more details with reference to FIG. 2.

In an embodiment of the semiconductor device according to the invention, the electrodes are structured with a first pitch, the bumps are structured with a second pitch, and the first pitch is not equal to the second pitch.

It is found to be possible to provide a bump pitch which substantially matches the pitch of the electrodes, to provide an IC chip with bump pitches which are larger or smaller than the pitch of the electrodes. In this way a chip may be used in a more versatile way for bonding purposes. Due to the fact that the area of individual bumps is larger than the area of the cooperating connectivity areas of the electrodes, the bumps are allowed to laterally displace with respect to the electrodes.

In accordance with embodiments of the invention it is possible to achieve not only an exact match between respective positions of the individual bumps and the corresponding bonding areas of a substrate, but also for a rough match there between. In this way larger misalignments between the bonding pads of the substrate and the electrodes of the IC chip are mitigated.

The method for manufacturing an integrated circuit according to an exemplary aspect of the invention comprises the steps of providing sets of integrated circuit (IC) chips having respective bumps connected to electrodes of an IC circuit. The bumps are arranged with respective pitches. The method further includes selecting a substrate including patterned bonding pads for bonding to the bumps. The method also includes measuring a value representative of distortion of a bonding pad pattern of the selected substrate. The method furthermore includes selecting an IC chip having a bump pitch substantially matching the distortion and bonding the selected IC chip to the substrate.

It is found to be advantageous to provide a plurality of pre-fabricated IC chips having different bump sizing for enabling versatile matching between the IC chip and a substrate the IC is conceived to be connected to. In particular, when a substrate conceived to be used for connectivity has different portions having different respective distortions, for example shrinkage, suitable differently sized IC chips are used for matching each such portion of the substrate. Alternatively, it is possible that in addition to intra-substrate sizing variation, inter-substrate variation also occurs. In this case, for each substrate, specifically sized IC chips are selected and applied. It will be appreciated that a plurality of methods are available to determine the value representative of distortion of the bonding pad pattern. In particular, for shrinkage, suitable distance between alignment marks is measured.

In an embodiment of the method according to exemplary embodiments of the invention the value is representative of substrate shrinkage and the respective bump pitches are patterned in accordance with collected data on substrate shrinkage.

The collected data is obtained from analyzing statistics of shrinkage measurements of a plurality of substrates. For example, a statistical distribution, like a curve or a histogram, may be determined for a number of substrates having specific degree of distortion (shrinkage) as a function of the distortion (shrinkage). Such distribution may be used to a-priori determine respective necessary stocks of IC chips having specific bump sizing, i.e., bump pitch, matching the distortion. These stocks are then used during a manufacturing process for individually matching substrates with correspondingly sized IC chips.

In a further embodiment of the method according to the invention the respective sets of IC chips with differently sized bumps are manufactured on a single wafer.

It is found to be advantageous to provide a stock of IC chips with differently sized bumps, i.e., with differently pitched bumps, substantially fitting a process demand. For example, when an empirically determined distribution of bonding pad distortion is taken into account, the number of IC chips per set may be manufactured accordingly, so that the respective stocks are emptied substantially simultaneous for each bump pitch. For this purpose a mask designed for patterning a single wafer may be used wherein such stock demands are taken into account. For example, for a Gaussian distribution of distortion of the bonding pads of suitable substrates a major part of the wafer is used for a central portion of the Gaussian distribution. The remaining area is suitably divided into a plurality of sub-regions, which may be identified in the Gaussian distribution. In this way on-demand stocks may be provided for enabling accurate manufacturing of an integrated circuit wherein misalignment errors between the bonding pads of the substrate and the bumps of the IC chips are mitigated.

These and other aspects of illustrative embodiments of the invention are further discussed with reference to drawings, wherein like reference signs represent like elements. It will be appreciated that the drawings are provided for illustrative purposes only and may not be used for limiting the scope of the appended claims.

### BRIEF DESCRIPTION OF THE DRAWINGS

While the claims set forth the features of the present invention with particularity, the invention, together with its objects and advantages, may be best understood from the following detailed description taken in conjunction with the accompanying drawing of which:

FIG. 1 schematically presents an embodiment of a cross-section of a semiconductor device according to the invention;

FIGS. 2A and 2B schematically present an embodiment of displacements of the bump with respect to the connectivity area of an electrode in the semiconductor device according to the invention;

FIG. 3 schematically presents an embodiment of a semiconductor device wherein a bump pitch is not equal to a pitch of the IC chip electrodes; and

FIG. 4 schematically presents an embodiment of an electronic apparatus comprising semiconductor device according to the invention.

### DETAILED DESCRIPTION

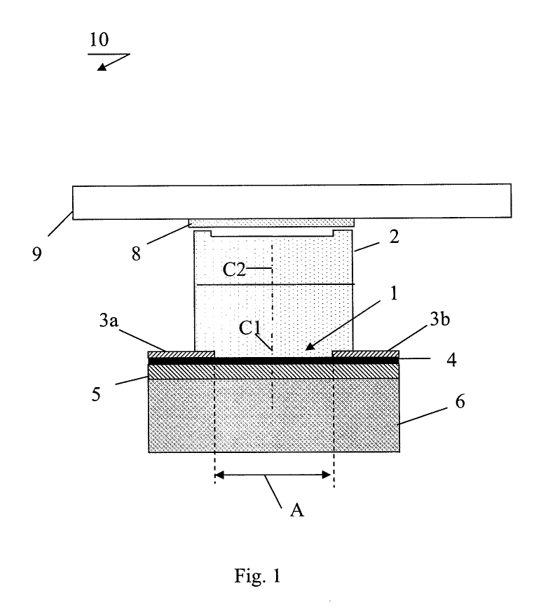

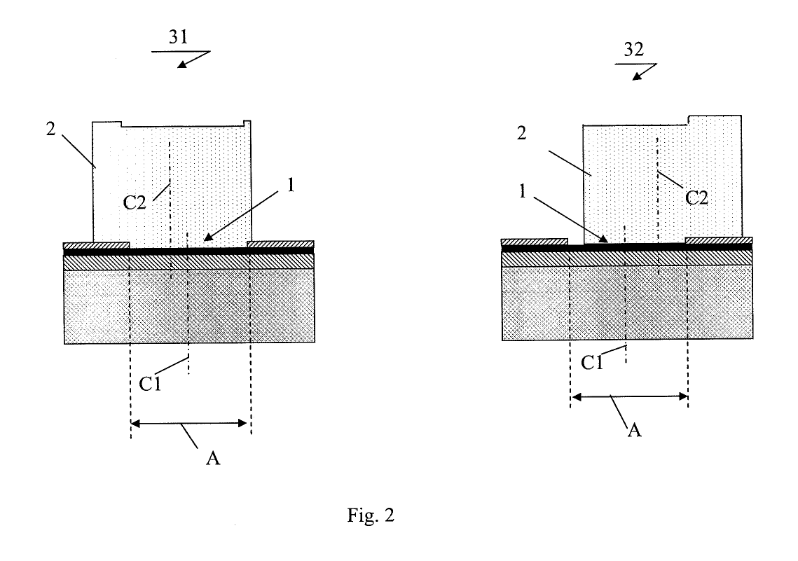

FIG. 1 schematically presents an embodiment of a cross-section of a semiconductor device according to the invention. Such semiconductor device may relate to a flip-chip IC 10, comprising an IC substrate 6, for example, silicon. The IC substrate 6 may include electrodes 4, wherefrom only one electrode is shown, which are conceived to engage in an electrical connection with respective bumps 2, thereby forming electrode-bump pairs. It will be appreciated that in practice the semiconductor device comprises a suitable plurality of such pairs shown in FIG. 1. As shown in FIG. 1, a passivation layer having portions 3a, 3b is deposited on top of micro-electronics 5 embedded in the IC substrate. The electrode 4 is patterned on the microelectronics layer 5. Holes 1 between the portions 3a, 3b of the passivation layer give access to the interconnect layers in the micro-electronics thereby defining connectivity areas A of the electrodes 4 for the bumps 2. With an extra process, suitable bumps 2, for example gold bumps, are formed atop the electrodes 4. These bumps may have a height in the order of 10-20 micrometers and are used to prevent lateral shorts between neighboring bumps. The lateral dimensions of the bump 2 is selected in such a way that a lateral dimension of the bump 2 is not equal to, for example is larger than, a corresponding lateral dimension of the connectivity area A. As a result an electrical connection is still enabled in cases when the bump 2 is misaligned with the electrode A, i.e. that a centreline C1 of the electrode does not lie on the same position as a centreline C2 of the bump (see FIG. 2). Alternatively, the lateral dimension of the bump 2 are smaller than the corresponding lateral dimension of the connectivity area A. It is possible to form either box-like bumps as shown in FIG. 1, or button-like bumps.

The IC substrate 6 including the bumps 2 is attached to a suitable electrode layer 8 of a substrate 9 using bonding glue (not shown). Preferably, the substrate 9 is flexible. The substrate 9 may relate to a display.

The extension of the bump 2 outside the connectivity area A of the electrode 4, for example atop the passivation layer 3a, 3b enables shifting the bump with respect to the hole 1 and/or the electrode 4 without negative consequences regarding bonding results. This is schematically shown as items 31, 32 in FIGS. 2A and 2B. The maximum bump shift, i.e. a distance between respective centrelines C1, C2 with respect to the IC length, determines an achievable sizing factor. This shift is obtained by a suitable measurement or based on analysis of a suitable plurality of deformed substrates, the IC chip is conceived to be connected to. After such information is collected, the bumps are sized properly by shifting them with respect to the underlying electrodes and/or by changing a pitch in the bump set.

IC sizing is done by using different bumping mask patterns in combination with possibly the same IC substrate. To create several differently sized IC's, a bumping mask can be designed such that it creates a differently sized IC as a function of location on the IC substrate. It is also possible to use several different bumping masks to create a full wafer of ICs scaled with a certain factor. The balance in numbers per IC size is, for example, based on statistics of substrate shrinkage. This has an advantage that the characteristics of the manufacturing process are analyzed and provide data for further optimization of the manufacturing process of the semiconductor device.

It will be appreciated that the semiconductor device according embodiments of the invention is used in the bonding area of a display, for example of a flexible display. The bonding area is usually used to provide electrical connectivity of display's electronics. In cases when statistics on shrinkage of the display substrate are collected, geometry of the bonding area is designed in such a way that after a nominal shrinkage of the display substrate, the shrunk substrate matches the nominally sized bumps of a suitable IC.

Alternatively, instead of placing the IC chip at a position on the substrate depending on the measured substrate shrinkage known, for example, from US 2005/0009219 A1, during manufacturing a best fitting IC is selected from a corresponding IC tray. First, a measurement of the substrate shrinkage has to be performed. This is done accurately by measuring the distance between known patterns arranged at known positions, for example by using the alignment marks at the left and right of the bonding area and comparing this number to the mask design. The shrinkage that is calculated is then used to make a selection from the available IC sizing options.

The device according to embodiments of the invention has an advantage particularly for higher interconnect densities. To meet such densities, more sophisticated bonding pad layouts are needed. The complexity of the layout is in general limited by the shrinkage correction method known, for example, from US 2005/0009219 A1. In accordance with illustrative embodiments, differently sized IC chips are manufactured from possibly the same underlying IC substrate patterns by varying a bump placement with respect to area connectivity area of electrodes, for example, with respect to a hole in the passivation layer of the IC substrate. By selecting the best fitting IC after measuring the shrinkage of the substrate, the bonding process can be made shrinkage tolerant, even for very complex bonding pad layouts of the substrate, such as, for example, multiple arrays or matrices of bonding pads.

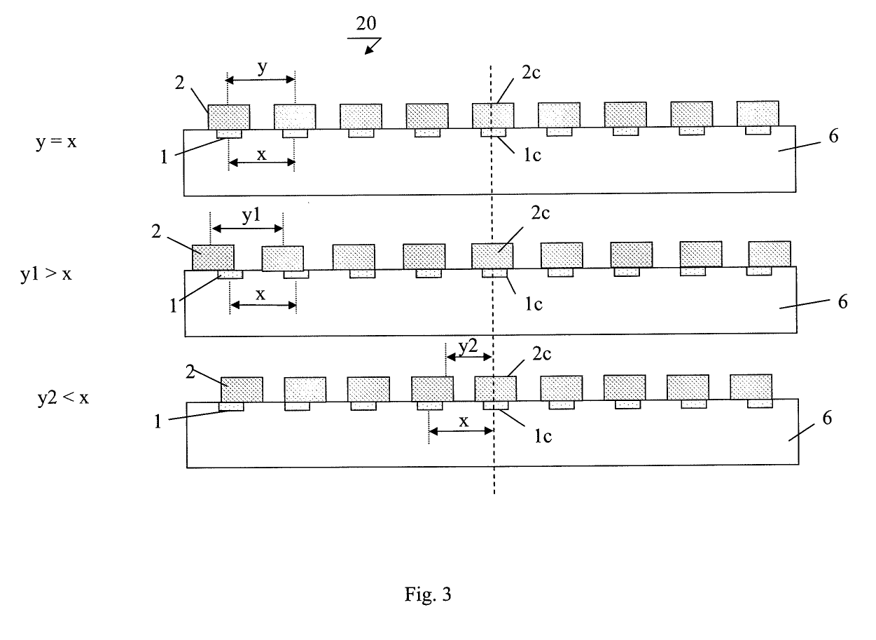

FIG. 3 presents a schematic view of an embodiment of a semiconductor device wherein a bump pitch is not equal to an electrode pitch. A semiconductor device 20 is manufactured so that a pitch x of the electrodes 1 is equal to the pitch y in the bumps 2. In this way an area of overlap between a bump and a corresponding connectivity area of the electrode is substantially the same for all bump/electrode pairs of the semiconductor device. In accordance with the illustrative embodiment, it is possible to manufacture a semiconductor device in such a way that a pitch y1 in the bumps 2 is larger than the pitch x in the electrodes (y1>x). In this way, for example, when a central bump 2c in a bump array is substantially centered about a central electrode 1c, the lateral bumps shift outwardly with respect to the respective electrodes. This has an effect that an area of overlap between a bump and an electrode is varied along the semiconductor device. Alternatively, it is possible that a pitch y2 of the bumps 2 is smaller than the pitch x of the electrodes (y2<x). In this way, for example, when a central bump 2c in a bump array is substantially centered about a central electrode 1c, the lateral bumps shift inwardly with respect to the electrodes. This also has an effect than an area of overlap between a bump and an electrode is varied along the semiconductor device. In accordance with the illustrative embodiments, use of chips with y=x, y1<x and y2>x during a manufacturing process of a semiconductor device, for example a display, leads to mitigation of displacement errors between bonding pads of a substrate 9 (shown in FIG. 1) and the bumps. This, in turn, enables manufacturing and application of semiconductor devices with higher electrode density, including, in the case of a display, enabling a higher matrix density.

Alternatively, for achieving a similar effect, it is possible to re-design a complete IC chip, for example, by allowing a pitch of the electrodes to vary. For example, the pitch of the electrodes x may be varied. The bumps having a constant pitch are then positioned atop of such electrodes.

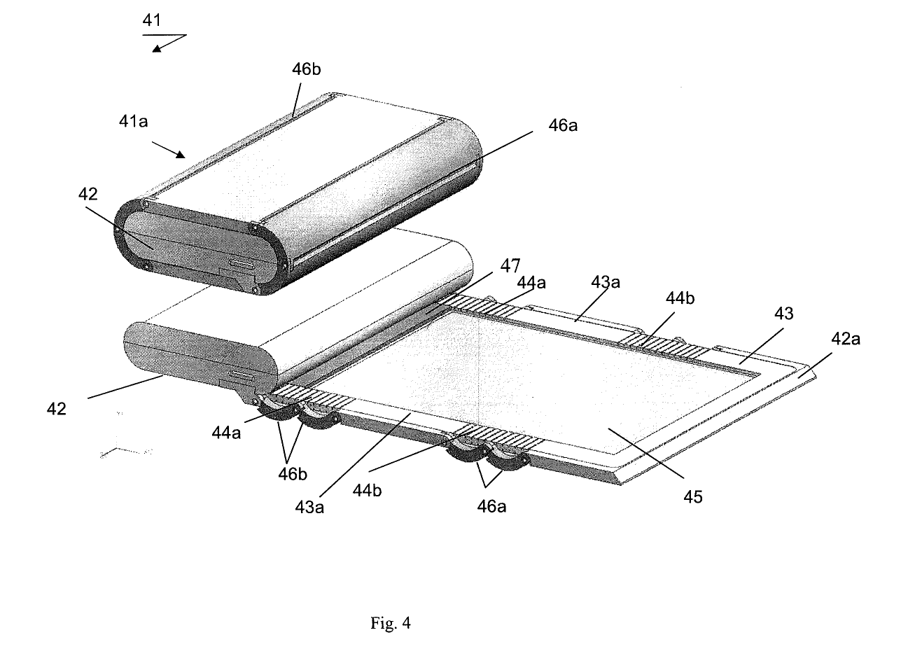

FIG. 4 schematically presents an embodiment of an electronic apparatus comprising semiconductor device according to the invention. The electronic apparatus 41 comprises a housing 42 and a retractable, notably wrappable, flexible display 45 that is arranged on a rigid cover 42a. The rigid cover 42a may be arranged to be wound together with the flexible display 45 around the housing 42 to a position 41a. The rigid cover 42a comprises an edge member 43 including rigid areas 43a and flexible areas 44a, 44b cooperating with hinges 46a, 46b of the cover 42a. When the flexible display 45 is being retracted to the position wound about the housing 42, the surface of the flexible display 45 may abut the housing 42. Functioning of the flexible display 45 is based on the integrated circuit chips bonded to the display substrate. In accordance with the illustrative embodiments, the electronic apparatus comprises IC chips discussed with reference to FIGS. 1, 2 and 3. The bonding area of the display is schematically indicated by 47. It will be appreciated that the electronic device comprising the flexible display is also arranged for storing the flexible display in a housing of the electronic apparatus rolled about a suitable roller. Rollable electronic displays are known in the art and they are also based on integrated circuits. In accordance with the illustrative embodiments, such integrated circuits are implemented as the semiconductor device discussed with reference to FIGS. 1, 2 and 3. It will further be appreciated that the electronic apparatus according to the illustrative embodiments also comprises a rigid display based on included integrated circuits, as discussed above, wherein respective IC chips are manufactured with a variable bump pitch, as discussed with reference to FIGS. 1, 2 and 3.

It will be appreciated that although specific embodiments of the structure according to the invention are discussed separately for clarity purposes, interchangeability of compatible features discussed with reference to isolated figures is envisaged. While specific embodiments have been described above, it will be appreciated that the invention may be practiced otherwise than as described. The descriptions above are intended to be illustrative, not limiting. Thus, it will be apparent to one skilled in the art that modifications may be made to the invention as described in the foregoing without departing from the scope of the claims set out below.

What is claimed is:

1. A semiconductor device, comprising:
an integrated circuit (IC) chip comprising:
a plurality of electrodes arranged in at least one row for enabling electrical connectivity to an IC chip circuit, said electrodes having centerlines in a direction transverse to a row direction; and
a plurality of bumps arranged atop the electrodes forming respective bump-electrode pairs, said bumps having centerlines in a direction transverse to the row direction,
wherein positions of bump centerlines with respect to electrode centerlines for the bump-electrodes pairs are different for different locations on the IC chip.

2. The semiconductor device according to claim 1, further comprising:
a passivation layer at least partially covering electrodes, said passivation layer including pre-manufactured holes forming respective connectivity areas on the electrodes.

3. The semiconductor device according to claim 1, wherein surface areas of bumps are not equal to the surface area of respective connectivity areas of electrodes.

4. The semiconductor device according to claim 2, wherein surface areas of bumps are not equal to the surface area of respective connectivity areas of electrodes.

5. The semiconductor device according to claim 1, wherein respective regions of overlap between the bumps and the cooperating electrodes of said pairs are different for different locations on the IC chip.

6. The semiconductor device according to claim 1, wherein the electrodes are structured with a first pitch, the bumps are structured with a second pitch, the first pitch being not equal to the second pitch.

7. The semiconductor device according to claim 1, further comprising a substrate having bonding areas, wherein respective bumps are connected to respective bonding areas.

8. The semiconductor device according to claim 7, wherein the substrate is flexible.

9. The semiconductor device according to claim 7, wherein the substrate comprises a display.

10. A method for manufacturing an integrated circuit comprising the steps of:
providing sets of integrated circuit (IC) chips having respective bump pitches connected to electrodes of an IC circuit, said bumps being arranged with respective pitches;
selecting a substrate including patterned bonding pads for bonding to the bumps;
measuring a value representative of distortion of a bonding pad pattern of the selected substrate;
selecting an IC chip having a bump pitch substantially matching said distortion; and
bonding the selected IC chip to the substrate.

11. The method according to claim 10, wherein said value is representative of substrate shrinkage and wherein respective bump pitches are patterned in accordance with collected data on substrate shrinkage.

12. The method according to claim 11, wherein said data is obtained from analyzing statistics of shrinkage measurements of a plurality of substrates.

13. The method according to claim 10, further comprising a step of pre-fabricating respective sets of IC chips having respective bump pitches based on said data.

14. The method according to claim 12, wherein said respective sets are manufactured on a single wafer.

15. The method according to claim 14 when dependent on claim 12, wherein a distribution of bump pitch sizing over the wafer substantially matches said statistics.

16. An electronic apparatus including a semiconductor device, the semiconductor device comprising:
an integrated circuit (IC) chip comprising:
a plurality of electrodes arranged in at least one row for enabling electrical connectivity to an IC chip circuit, said electrodes having centerlines in a direction transverse to a row direction; and
a plurality of bumps arranged atop the electrodes forming respective bump-electrode pairs, said bumps having centerlines in a direction transverse to the row direction,
wherein positions of bump centerlines with respect to electrode centerlines for the bump-electrodes pairs are different for different locations on the IC chip.

17. The semiconductor device according to claim 16, wherein a passivation layer is provided at least partially covering electrodes, said passivation layer including pre-manufactured holes forming respective connectivity areas on the electrodes.

18. The semiconductor device according to claim 16, wherein surface areas of bumps are not equal to the surface area of respective connectivity areas of electrodes.

19. The semiconductor device according to claim 16, wherein the electrodes are structured with a first pitch, the bumps are structured with a second pitch, the first pitch being not equal to the second pitch.

20. The semiconductor device according to claim 16, wherein further comprising a substrate having bonding areas, wherein respective bumps are connected to respective bonding areas.

21. The semiconductor device according to claim 16, comprising a display.

22. The semiconductor device according to claim 21, wherein the display is flexible.
